(19) United States
(12) Patent Application Publication
(10) Pub. No.: US 2022/0228356 A1
(43) Pub. Date: Jul. 21, 2022

(54) ACTIONABLE STORMWATER SERVICES PLATFORM

(71) Applicant: Arcadis U.S., Inc., Highlands Ranch, CO (US)

(72) Inventors: Mostafa Elag, North Bethesda, MD (US); Renan Fernando Pasquel, Fairfax Station, VA (US)

(21) Appl. No.: 17/581,059

(22) Filed: Jan. 21, 2022

Related U.S. Application Data
(60) Provisional application No. 63/140,017, filed on Jan. 21, 2021.

(51) Int. Cl. E03F 1/00; G01N 11/00; G06N 5/02

(52) U.S. Cl. CPC E03F 1/00; G01N 2011/0026; G06N 5/022; G01N 11/00

(57) ABSTRACT

A water analytics (or actional stormwater services) platform is disclosed wherein the platform allows for keeping up with the most recent data and industry standards and gives flexibility to meet client (e.g., citizens, city managers, stormwater/conveyance system operators) needs. The platform evaluates the site-specific and collective impacts of individual flood events and presents value risk assessments. The platform estimates direct physical damages and provides related analysis for implementation and assessment by end-users. Some preferred embodiments include additional modules for direct and indirect loss of public service and their impacts to the service population.

### CROSS-REFERENCE TO RELATED APPLICATION

This application claims the benefit of and priority from U.S. provisional application No. 63/140,017 filed on Jan. 21, 2021 and entitled WATER ANALYTICS PLATFORM. The contents of the above applications are hereby incorporated herein by reference in full.

### FIELD OF INVENTION

The present disclosure relates to predictive decision support systems and Hydro-informatics technologies to provide users with recommended actions to mitigate the impact of an upcoming storms event and improve the operations of stormwater/conveyance systems. The disclosure integrates Internet of Things, Web Services, Hydrology and Hydraulic modeling, machine learning, predictive data analytics, and visualization. The application introduces for stormwater/conveyance system operators, municipalities, and citizens a timely actionable flood mitigation scenario for a storm that may happen in the upcoming future, for example, the next 48 hours. It aims to reduce the risk of property and infrastructure damage, as well as enhance community safety and resilience.

### BACKGROUND

Cities are vulnerable to extreme rainfall and urban flooding disasters. This vulnerability increases significantly in cities impacted by climate change and Sea Level Rise (SLR). Given the current and future changes on the magnitude and duration of storm events, integration of hydrologic and hydraulic modeling with real-time data is critical to improving management of stormwater/conveyance systems and reducing flood risks. Better stormwater resilience planning is needed for building an efficient seamless integration between weather data and hydrologic and hydraulic models, developing proper interpretation of the simulation scenarios in real-time, and sharing results among watershed stakeholders and city managers. Despite the availability of different hydrologic and hydraulic models and their ability to simulate historic events, the technology of connecting models with data, predicting and identifying the impact of an upcoming storm event present real challenges.

Additionally, stormwater/conveyance systems are out of sight assets. Aging of these buried assets is a looming threat to all utilities because they are difficult to inspect, can catastrophically fail, and are costly to replace. Stormwater/conveyance systems usually lack data processing in real-time to support actions and efficient operation. The technology for understanding the impact of upcoming storm events on the system is not available yet. These systems are assumed to be operating to specification unless there is a major problem (i.e., clogging, structural failures, capacity limits, etc.). Therefore, there is a need for a new technology to assess the impact of upcoming storms and identify critical points in the stormwater/conveyance network and recommend solutions for users.

Today, real-time data analytics and Internet of Thing (IoT) provides developers and users with a powerful tool that can extract insights and support actions in real-time. The operator of the system can elevate the performance of the system even with scarce financial resources. The wastewater and stormwater sectors are, in some cities, data-rich, but poor in the data analytics tools. Collecting vast troves of data that can be used to derive, understand, and analyze relationships about system performance will provide insights for operators to better manage the system. In addition, the collected data can be combined and compared against a physical model of operation to inform the process and maximize efficiency. Data-analytics in a real-time approach can provide insights to understand the performance of the infrastructures and use this information to maximize their operational availability and capacity within a constrained budget.

The presently disclosed an actionable stormwater services platform (or water analytics platform) brings together methodologies, not currently available in the art. The platform's adaptability allows for keeping up with the most recent data and industry standards and gives flexibility to meet various city and system needs. The platform currently evaluates site-specific and collective impacts of individual flood events and presents value risk assessments. The platform estimates direct physical damages, problem areas within the stormwater/conveyance system, and provides related analysis for implementation and assessment by end-users. Some preferred embodiments include additional modules for direct and indirect loss of public service and their impacts to the service population.

### SUMMARY

The following presents a simplified summary of embodiments of the present invention in order to provide a basic understanding of such embodiments. This summary is not an exhaustive overview of all contemplated embodiments, and is not intended to delineate the scope of all embodiments.

The present disclosure provides a predictive decision support system that relies on integrated information technology. The innovation integrates Internet of Things, Web Services, Hydrologic and Hydraulic modeling, machine learning, predictive data analytics, and visualization to provide users with recommended actions to mitigate the impact of the upcoming storms.

The platform provides two alternatives for predicting the impact of upcoming, for example the next 48 hours, storm event on the storm/sewer collection system, estimating streets that will be flooded, identifying vulnerable facilities, prioritizing critical areas, and/or providing recommendations for the actions and measures that need to be taken to mitigate the storm impact and better operate the system. The two alternatives include: (i) physical-based alternative, which relies on the well-calibrated hydraulic model to estimate the storm impact, and (ii) machine-learning alternative, which depends on a neural network for estimating the storm impact.

The objective of the present invention is to provide an information capturing and processing flood risk assessment system and method, comprising a mobile computing device for receiving a plurality of user input data. In some embodiments, the mobile computing device is configured to receive the user input data from a user at the mobile computing device, as well as receive third-party data from individual service providers at the mobile computing device. The user input data and third-party data may comprise, in some embodiments, digital data, further comprising climate data, remote sensing, flow monitoring data, and a list of vulnerable assets.

The summary above is neither intended nor should it be construed as being representative of the full extent and scope of the present disclosure. The present disclosure is set forth in various levels of detail in the summary, as well as in the attached drawings and the detailed description below. No limitation as to the scope of the present disclosure is intended by either the inclusion or non-inclusion of elements, components, etc. in this summary. Additional aspects of the present disclosure will become more readily apparent from the detailed description, particularly when taken together with the drawings.

### BRIEF DESCRIPTION OF THE DRAWINGS

FIG. 1 is a schematic illustrating the evolution of flow analytics and its relationship with industrial tools and public domain data to support different sectors in a collection (stormwater/conveyance) system;

FIG. 2 is a schematic illustrating the design of an embodiment of the present invention, an actionable stormwater services platform;

FIG. 3 is a schematic illustrating the design of an embodiment of the present invention, an actionable stormwater services platform built with three interacting core modules;

FIG. 4 is a schematic illustrating the communication sequence between a platform data fetcher service and NOAA (National Oceanic and Atmospheric Administration) application programming interface;

FIG. 5 is an illustration of storm evaluation process;

FIG. 6 is an illustration of the three-layer network of a flow neural network;

FIG. 7 is an illustration of a summary of the possible storm event for the next 48 hours and identify its return period to characterize its impact on the conveyance system;

FIG. 8 is an illustration of summary of predicted bottle necks for a conveyance system under a possible storm event;

FIG. 9 is an illustration of summary of inferred street hotspots (flooded streets) under the next 48-hour storm event;

FIG. 10 is an illustration of defining asset criticality level under a projected storm event.

### DETAILED DESCRIPTION

The detailed description herein makes reference to the accompanying drawings and/or figures, which show the exemplary embodiment by way of illustration and its mode. While these exemplary embodiments are described in sufficient detail to enable those skilled in the art to practice the invention, it should be understood that other embodiments may be realized and that logical and mechanical changes may be made without departing from the spirit and scope of the invention. Thus, the detailed description herein is presented for purposes of illustration only and not of limitation. Moreover, any reference to singular includes plural embodiments, and any reference to more than one component may include a singular embodiment.

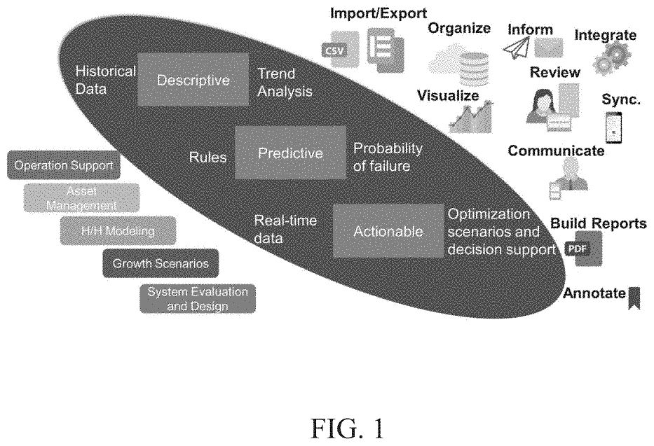

FIG. 1 illustrates the relationships among the levels of storm analytics, available industrial tools, and their roles in supporting different stormwater/conveyance system sectors. Flow analytics has three levels. First, “Descriptive” analytics allows a user to analyze historical data/events and understand the flow conditions during an event period. This tool is suitable for supporting Hydrologic-Hydraulic planning and evaluation, and trend analysis. Second, “Predictive” analytics relies on logic rules and statistical models to predict the probability of failure for a system component. This level supports asset management and growth scenarios evaluations. Finally, “Actionable” analytics, which aims to combine real-time and possible storm events data analysis with logic rules to identify and characterize the flow condition in real-time to support decision-makers at different levels. These three levels of storm analytics cannot be achieved without the support of industrial tools such as data processing and report building tools. While these tools are essential for the development of the actionable analysis, there are key components that required to build an actionable environment such as setting logic rules for flow characterization.

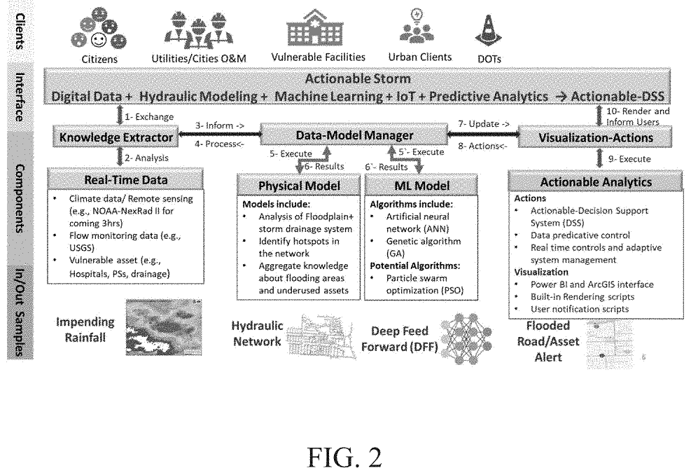

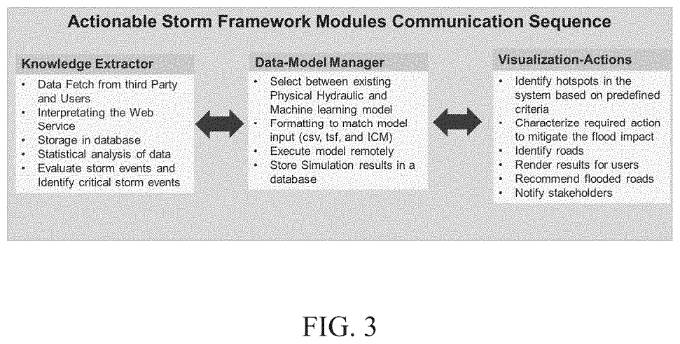

FIG. 2 illustrate an embodiment of the design of an actionable stormwater services platform. The platform comprises two layers: (1) an interface that includes the algorithms, user input, connection to databases endpoint, and visualization layers, which represent the interactive interface between users and the platform, and (2) components layer that includes the databases (such as climate data, remote sensing data, flow monitoring data, vulnerable asset data, floodplain data, and storm drainage system data), physical and machine learning models that operate remotely, and actionable analytics. The components layer has three modules: Knowledge Extractor, Data-Model Manager, and Visualization-Actions modules. See also, FIG. 3. The communication between the modules, interface, and data sources are illustrated in FIG. 2. The Knowledge Extractor exchanges information with the users and external databases endpoint through the interface. Then, it informs the Data-Model Manager with critical events that are greater than a pre-defined storm event (intensity, duration, and return period). For critical events, the manager process the data and integrate it with the appropriate model either physical or Machine Learning (ML) models. After the analysis is completed, the Data-Model Manager updates the internal database with results and inform the Visualization-Action Module with the results, where it starts identifying hotspots in the system and recommend actions. Then, the Visualization-Action module informs users through the interface about the required actions and render the critical points in the system. The platform can serve different types of client that interact with the stormwater/conveyance system. It ingests weather data from different sources and produce multiple outputs including maps that reflect the impact of a coming storm events on the system.

The platform automates the integration between weather data, which is the key driver in system, with Hydrologic/Hydraulic (H/H) models. The platform brings predicted weather data for the near future, for example, the next 48 hours, summarizes the storm characteristics, and evaluates its return period based on the Intensity Duration Frequency (IDF) curves associated with the concerned area. The platform provides outputs that may include the following:
A statistical summary of a possible storm event in the next 48 hours.
An evaluation of return period of the storm event based on the Intensity Duration Frequency (IDF) curves associated with the area of concern.
Hydraulic response of the network to the possible storm event in the next 48 hours.
Predicts, annotates, and recommends possible solutions for the bottle necks (e.g., obstructions, lack of capacity, etc.) of a stormwater/conveyance system (storm and sewer) under the possible storm event using a bi-directional workflow that runs a calibrated hydrologic and hydraulic model of the system and present the system performance for operators using an interactive Geographic Information System (GIS)-based visual.
Identifies streets hotspots (flooded streets) under the next storm event using a bi-directional workflow that runs a 2D-Hydrology model and presents results to user (e.g., citizens, city managers, system operators) using an interactive dashboard.
Defines asset criticality level under the projected storm event. For example, the invention defines the criticality level of lift stations (pumps) under the projected storm event using a flood control algorithm in hydraulic network, a logic algorithm that analyzes the simulation output, identifies and annotates critical elements (nodes, pipes, and pumps), e.g., vulnerable assets that might be subject to failure or overload, in the system, and provides user with recommended action—if the network has the capacity to mitigate the upcoming storm's impacts. In the case of Pump Station, the algorithm identifies if the pump is short in capacity due to increase in the upstream flow, or if the pump is submerged due to surface runoff and will be unreachable during the storm event or if the pump will be subjected to both system capacity and accessibility issue during storm event.

As illustrated in FIG. 3, the components layer of the platform integrates three main modules: Knowledge Extractor, Data-Model Manager, and Visualization-Actions modules. The Knowledge Extractor is responsible for data processing and evaluation of the possible upcoming storm event. The Data-Model Manager runs a continuous simulation model with updated parameters and update the database with simulation results. The Visualization-Actions component is responsible for rendering the results and applying the action logics to inform users. The three modules are loosely coupled where they can be independent or integrated in a different workflow.

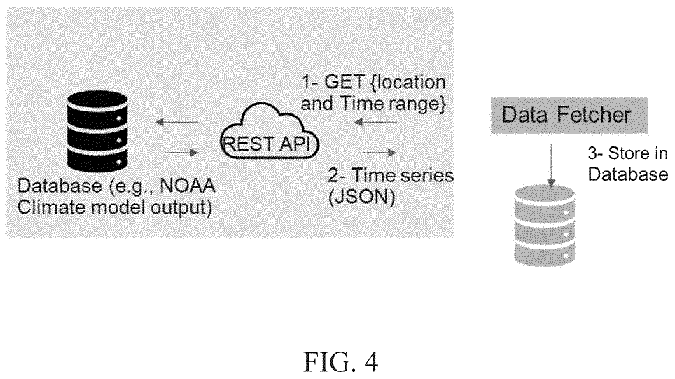

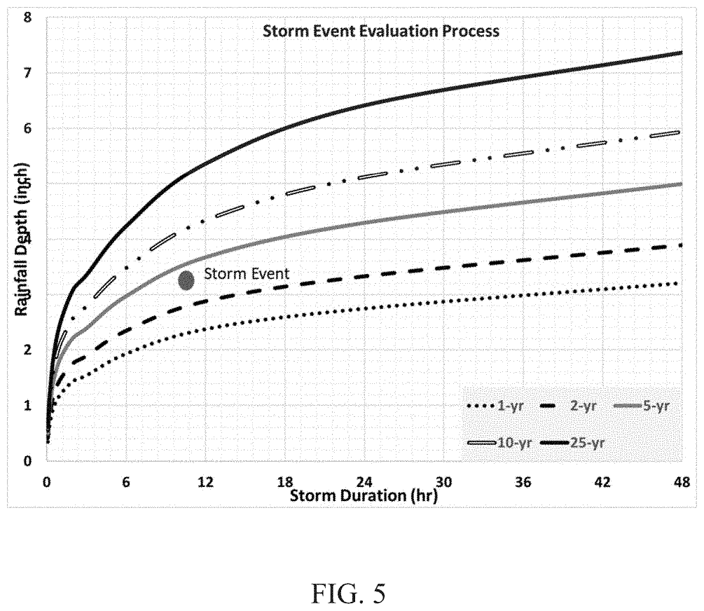

The Knowledge Extractor includes a set of Web services that can communicate with weather databases that have Application Programming Interface (API) such as NOAA to bring weather information (e.g., climate data, remote sensing data), including precipitation and/or tide level for the next 48 hours. The services use REST API (also known as RESTFul API) services and store the incoming data in local database. FIG. 4 illustrates the communication sequence between the web service and NOAA server to extract the predicted rainfall data for the next 48 hours. Data is first extracted from NOAA database through REST API services. The response of NOAA website is Java Script Object Notation (JSON) format, the knowledge extractor interprets the response and convert it to an Access database format and store it in the local database. The data may be stored in a separate local database. The total depth and storm duration of the predicated storm event is used to evaluate its return period based on the Intensity Duration Frequency Curve (IDF), which is imported from NOAA. As illustrated in FIG. 5, NOAA provides IDF curves for 1-year, 2-year, 5-year, 10-year, 25-year storms and also larger storms, in some cases. Superimposing the predicted storm event on the IDF curves (FIG. 5) provides end users visual evaluation of the expected storm event.

The Data-Model Manager is an intermediate module that integrates the data with the appropriate model. For example, some areas may have a Hydrologic and Hydraulic (H/H) one dimensional (1D) model and have a rain on mesh model. The Data-Model Manger processes the forecasted weather data including precipitation, temperature, and tide information, if available, to the H/H model. The module is responsible for formatting the weather data to match the H&H model input requirements. It has two format converters that extract the data from the database and format them to match EPA's Storm Water Management Model (SWMM)-based models. The Data-Model Manager is connected with either a previously calibrated physical model or neural network model (e.g., artificial neural network algorithm). The Data-Model Manager is responsible to run the model and store the simulation results in the local database.

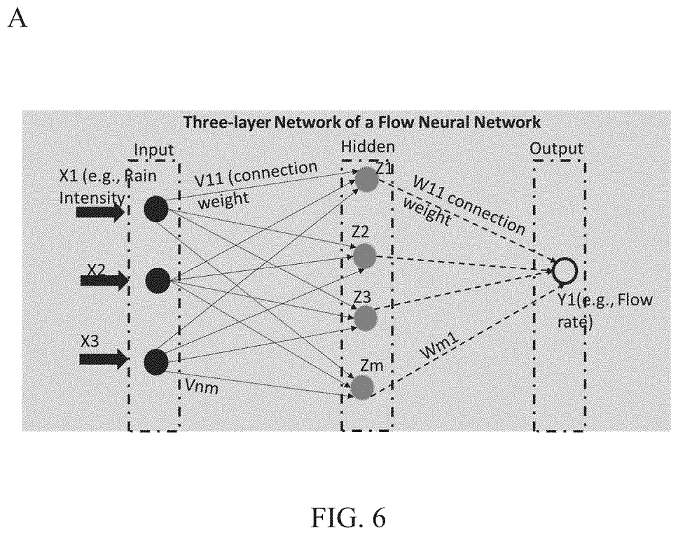

In one embodiment, the artificial neural network algorithm for flood hydrograph uses three-layer network as shown in FIG. 6. The Artificial Neural Network (ANN) consists of neurons. It learns and stores information through the training process. The ANN shown in FIG. 6 represents a flow hydrograph prediction in an actionable stormwater services platform. The compacted input values (xi) are first entered into the input layer neurons. The input is the precipitation rate (for example, from third party climate data or remote sensing data). They are multiplied by the connection weights (vᵢⱼ) and then passed on to the hidden layer neuron, which preforms nonlinear transformations of the inputs (e.g., rainfall intensity over a catchment) entered to the network to produce simulation outputs (e.g., flow rate at pipe downstream the catchment). The transformation function depends on pipes attributes (e.g., sewer pipe) diameter and slope. Each neuron sums all the received weighted information (xᵢvᵢⱼ) and then passes the sum through an activation function to produce an output (zᵢ), which in turn, becomes the input signal for the output layer neuron. At the training phase of the model, the flow at the outputs is matched with the historical events, to ensure the quality of the existing model. Then the errors that represents the difference between the observed flow and the simulated flow are used to update the connection weights using the back propagation algorithm, which minimizes the error function by using the gradient decent method, which is described in Algorithm 1. The output from each inner layer neuron is multiplied by the related connection weight (wᵢⱼ) and then passed on to the output neuron, which sums all the received signal (zᵢwᵢⱼ) and passes it through an activation function to produce the network output (yᵢ)

One embodiment of the neural network algorithm (Algorithm 1) is shown below:

| | |
|---|---|
| 1- | Let |
| | a. Xᵢ be the input value for a node in the input layer |
| | b. Vᵢⱼ connection weight between input layer and hidden layer depends on pipe |
| | diameter and slope |
| | c. Zᵢ output of the hidden layer that becomes input for the final layer |
| | d. Wᵢⱼ connection weight between hidden layer and output layer-based pipe |
| | diameter and slope |
| | e. Yᵢ network output |
| | f. tᵢ is the user specified flow based on historical events |
| | g. p is the number of training patterns |
| | h. δ learning rate |
| | i. α momentum factor |
| | j. xₘₐₓ is the max value received by neuron |
| | k. xₘᵢₙ is the min value received by neuron |
| 2- | Average weight of information/neuron (wᵢ) = XᵢVᵢⱼ |
| 3- | Zᵢ = ΣWᵢ |
| 4- | Yᵢ₌ ZᵢWᵢⱼ |
| 5- | $Minimized Error Function E = {\sum }_{i}^{P} {( {t}_{i} - {Y}_{i} )}^{2}$ |
| 6- | $Δ {W}_{ij} ( n ) = α Δ ( n - 1 ) - δ ( \frac{δ E}{δ {W}_{ij}} )$ |
| 7- | ΔWᵢⱼ(n) = Wᵢⱼ^{old} − Wᵢⱼ^{new}/at present iteration (n) |
| 8- | ΔWᵢⱼ(n − 1) = Wᵢⱼ^{old} − Wᵢⱼ^{new}/at previous iteration (n − 1) |
| 9- | $f ( info ) = \frac{2}{1 + {e}^{- 2 info}} - 1 \text{/} info total information received at the neuron$ |
| 10- | ${z}_{i} = [ \frac{1.8 ( xi - {x}_{min} )}{{x}_{max} - {x}_{min}} ] - 0.9$ |

The Visualization-Actions module comprises two main sub-modules: (i) actions that have algorithms for building decisions based on flood control algorithm (Algorithm 2) and flood assessment algorithm (Algorithm 3), and (ii) visualization component (which may be achieved though Power BI dashboard, a web-based data management system that allows visualization, interactive collaboration, and provenance tracking of data files). The present invention transfers the graphs and plots from a desktop application to a scalable web-based application that is then used to create graphs with multiple adjustments, given basin-specific parameters, which allows comparison of results.

Algorithm 2 (flood control algorithm in hydraulic network) analyzes the simulation output, identifies and annotates critical elements (nodes, pipes, and pumps), e.g., vulnerable assets that might be subject to failure or overload beyond capacity limit, in the system, and provides user with recommended action—if the network has the capacity to mitigate the upcoming storm's impacts. Below is an embodiment of Algorithm 2 wherein “n” be a node in network of Nodes N, “c” be a conduit in a network of conduits C, and “p” be a pump in network of Pumps P.

| | |
|---|---|
| 1- | Let λ be a simulation result |
| 2- | For all n in N |
| | a. Compare Hydraulic Grade Line (HGL) with Top of |
| | cast level (TOC) |
| | b. If λn_{HGL} > n_{TOC} then |
| | i. Overflow = λn_{HGL} − n_{TOC} |
| | ii. Annotate node “Overflow” |
| 3- | For all c in C |
| | a. Compute Cap = λd_{c-sim}/c_{depth} |
| | b. If Cap > 80% then |
| | i. Annotate pipe as “Partially Full” |
| | c. If Cap > 100% then |
| | i. Annotate pipe as “Surcharged” |
| | d. Else |
| | Annotate Pipe as “Normal Flow” |
| 4- | For all p in P |
| | a. Compute flow volume difference p_{flowdiff} = Σλp_{outflow} − Σp_{inflow} |
| | b. If p_{flowdiff} < 0 then |
| | i. Annotate pump with “Capacity Failure” |
| | c. Else |
| | i. Annotate pump as “Normal Operation” |
| | d. Calculate stage-storage of the Pump station watershed |
| | e. If the water level > TOC of the pump intake node then |
| | i. Annotate pump as “submerged” |
| | f. Else |
| | i. Annotate pump as “not impacted by surface flow” |
| | g. If P is “Submerged” Π “Capacity Failure” Π Pump |
| | capacity > threshold ranges/defined based on system |
| | operator, then: |
| | i. Asset Critically level == “High” or “Normal” or “Low” |
| 5- | Export annotation to database |

Algorithm 3 (flood assessment algorithm in rain over mesh) analyzes the simulation results, identifies and flags flood spots on the mesh, and clusters the water depth of mesh pixels to characterize potentially flooded roads and houses. The algorithm provides notifications to users of the critical spots and recommended actions—if the system has the capacity to mitigate the upcoming storm's impacts. Below is an embodiment of Algorithm 2 wherein “n” be a node in 2D mesh N, “r” be road in the road network R, “s” be a storm inlet in storm network, and “p” be a pump in network of Pumps P.

| | |
|---|---|
| 1- | Let λ be a simulation result |
| 2- | Create a heat map of the water depth |
| 3- | For all s in S: |
| | a. Compare Water Depth (WD) with Top of cast level (TOC) |
| | b. If λ_{WD} > n_{TOC} then |
| | i. Annotate node as “submerged” |
| | ii. Assign red flag for the node to identify potential need |
| | for cleaning before storm |
| | c. Else |
| | i. Annotate node with “Normal flow” |
| 4- | For r in R: |
| | a. Compare Water Depth (WD) with nearby road elevation |
| | b. Spatially cluster the WD of pixels around roads |
| | c. Create a connection between clusters |
| | d. Interpolate the between clusters |
| | e. Identify water depth over the road (WD_Rd) = |
| | interpolated WD − road elevation/at each pixel |
| | f. If WD_RD > threshold/defined based on road level |
| | of service, then |
| | i. Annotate road segment as “flooded” |

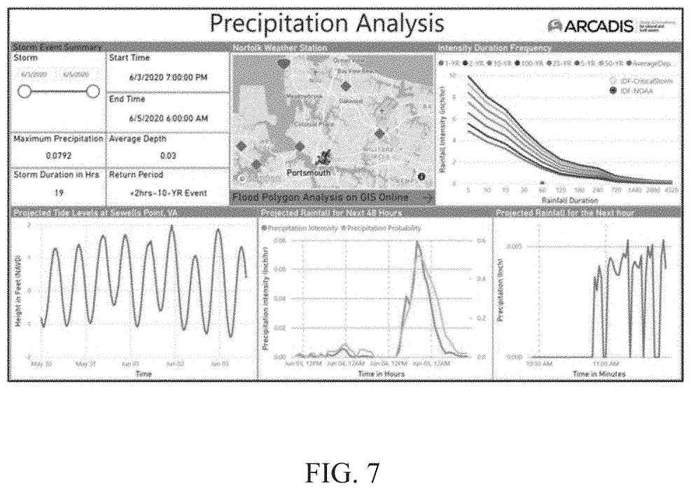

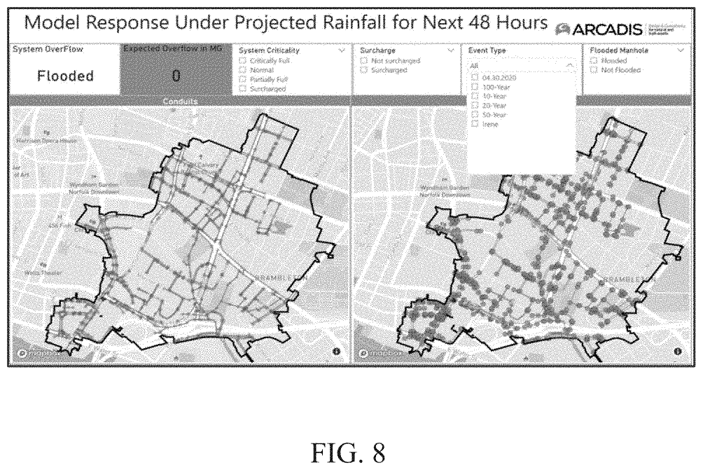

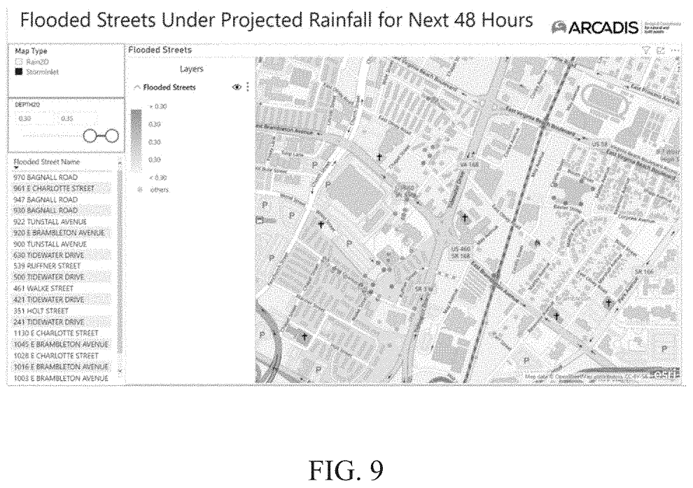

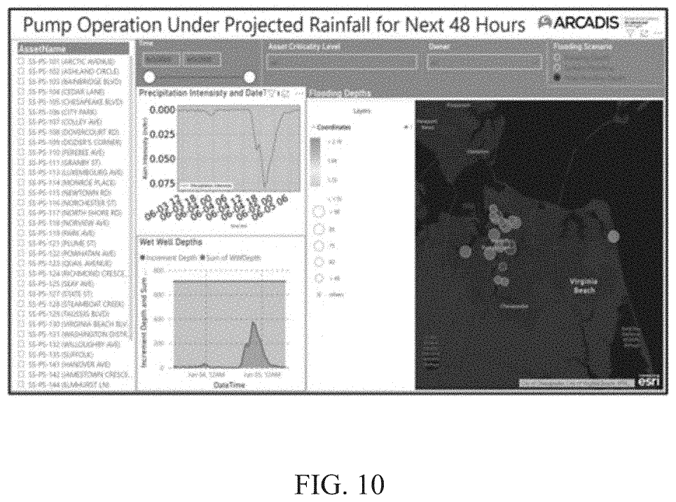

In one embodiment, the visualization is provided through a Power BI dashboard that may include the following visuals:
Statistical summary of the possible upcoming storm event for the next 48 hours and identification of its return period to characterize the impact on the stormwater/conveyance system. Additionally, the visualization may provide a location maps that defines the location of NOAA stations, and the United States Geological Survey (USGS) flow monitoring gauges that are used in hydrology model calibration. See FIG. 7.
The predicted bottle necks (e.g., obstructions, lack of capacity, flooded manholes, etc.) for a conveyance system under the possible storm event using a bi-directional workflow that runs a calibrated hydrologic and hydraulic model of the system and presents the current system performance for operators using an interactive GIS-based visual. The visualization also may provide a user with (i) visual comparison of the expected storm event with older storm event, for example Hurricane Irene; and (ii) filtering the network based on the criticality level, which is useful to identify facilities that may have a problem due to the coming storm event. There are helpful to understand the impact of the coming storm event. See FIG. 8.
The inferred streets hotspots (flooded streets) under the next storm event using a bi-directional workflow that runs a 2D-Hydrologic model and presents results to the user (e.g., citizens, city managers) using an embedded GIS visual in Power BI interactive dashboard. The visual may provide users with the ability to change the threshold for water depth (flood depth) based on their need and experience in the area. Then the visual is connected with the Algorithm 3 (flood assessment algorithm in rain over mesh) to analyze the results cluster the water depth of mesh pixels to characterize potentially flooded roads and houses. The visual may also extract the name of the flooded streets and list them based on criticality (flood depth) for users to identify action priority. See FIG. 9.
Defines asset criticality level under the projected storm event. For example, the application defines the criticality level of lift stations under the projected storm event using a logic algorithm that combines pump attributes and a combination between system capacity and expected surface runoff water. Then start to annotate vulnerable pump station to inform operators. The main visual (on the right side) uses color coding and size to flag the criticality of the asset (e.g., pump station). The middle visual provides a user with two sub-visuals (i) first visual identifies on the fly the water depth in the pump station's wet well based on the coming storm event; and (ii) second visual plots the rainfall intensity and duration curve. The combination between these two visuals allow users to review the projected response of the system with the potential storm event from any device on the fly without a need for desktop application. In addition, the visual provides a user with the ability to filter the pump stations based on criticality level, flooding scenario (system capacity issue, ponding water, or both), owner of the pump station. Finally, the left part of the visual introduces for the user the ability to select an asset and visually navigate to its geographic location to review the accessibility conditions and identify the areas that will be impacted by the coming storm event. Then the visual starts to automatically update the asset performance curves exemplified in wet well depth. This filter allow users to select more than one pump Station to compare their performance. See FIG. 10.

The previous description of the disclosed examples is provided to enable any person of ordinary skill in the art to make or use the disclosed apparatus. Various modifications to these examples will be readily apparent to those skilled in the art, and the principles defined herein may be applied to other examples without departing from the spirit or scope of the disclosed apparatus. The described embodiments are to be considered in all respects only as illustrative and not restrictive and the scope of the invention is, therefore, indicated by the appended claims rather than by the foregoing description. All changes which come within the meaning and range of equivalency of the claims are to be embraced within their scope. Skilled artisans may implement the described functionality in varying ways for each particular application, but such implementation decisions should not be interpreted as causing a departure from the scope of the disclosed apparatus.

What is claimed is:

1. An actionable stormwater services platform comprising:
a mobile computing device configured to receive user input data from a user at the mobile computing device and third party data in real time at the mobile computing device, wherein the user input data comprises a set of requirement by the user, and the third party data comprises climate data, remote sensing data, floodplain data, and storm drainage systems data;
a knowledge extractor module configured to extract the third party data;
a data-model manager module configured to integrate the user input data and the third party data, wherein the data-model manager module comprises a neural network algorithm for flood hydrograph configured to analyze the user input data and the third party data and provide a simulation output based on the user input data and third party data;
a visualization-actions module configured to provide a visualization to the user via the mobile computing device, wherein the visualization-actions module comprises a flow control algorithm configured to analyze the simulation output and identify assets that might be subject to overload beyond capacity limit or failure, and a flood assessment algorithm configured to analyze the simulation output and identify potentially flooded area.

2. The actionable stormwater services platform of claim 1 wherein the third party data further comprises flow monitoring data.

3. The actionable stormwater services platform of claim 1 wherein the third party data further comprises vulnerable asset data.

4. The actionable stormwater services platform of claim 1 wherein the user input data further comprises vulnerable asset data.

5. The actionable stormwater services platform of claim 1 wherein the visualization comprises a summary of possible upcoming storm event and identification of the storm event's return period.

6. The actionable stormwater services platform of claim 1 wherein the visualization comprises prediction of bottle necks for a water conveyance system.

7. The actionable stormwater services platform of claim 1 wherein the visualization comprises identification of one or more potentially flooded streets.

8. The actionable stormwater services platform of claim 1 wherein the visualization comprises identification of an asset's criticality level under a projected storm event.

9. A method for providing actionable stormwater services comprising:
receiving user input data from a user at a mobile computing device and third party data in real time at the mobile computing device, wherein the user input data comprises a set of requirement by the user, and the third party data comprises climate data, remote sensing data, floodplain data, and storm drainage systems data;
using a knowledge extractor module configured to extract the third party data;
using a data-model manager module configured to integrate the user input data and the third party data, wherein the data-model manager module comprises a neural network algorithm for flood hydrograph configured to analyze the user input data and the third party data and provide a simulation output based on the user input data and third party data;
using a visualization-actions module configured to provide a visualization to the user via the mobile computing device, wherein the visualization-actions module comprises a flow control algorithm configured to analyze the simulation output and identify assets that might be subject to overload beyond capacity limit or failure, and a flood assessment algorithm configured to analyze the simulation output and identify potentially flooded area.

10. The method of claim 9 wherein the third party data further comprises flow monitoring data.

11. The method of claim 9 wherein the third party data further comprises vulnerable asset data.

12. The method of claim 9 wherein the user input data further comprises vulnerable asset data.

13. The method of claim 9 wherein the visualization comprises a summary of possible upcoming storm event and identification of the storm event's return period.

14. The method of claim 9 wherein the visualization comprises prediction of bottle necks for a water conveyance system.

15. The method of claim 9 wherein the visualization comprises identification of one or more potentially flooded streets.

16. The method of claim 9 wherein the visualization comprises identification of an asset's criticality level under a projected storm event.
